(19) United States
(12) Patent Application Publication
(10) Pub. No.: US 2025/0372542 A1
(43) Pub. Date: Dec. 4, 2025

(54) SEMICONDUCTOR STRUCTURE, AND METHOD FOR FABRICATING A STACKED DIE

(71) Applicant: TAIWAN SEMICONDUCTOR MANUFACTURING COMPANY, LTD., Hsinchu (TW)

(72) Inventors: Feng-Chien HSIEH, Hsinchu (TW); Wei-Li HU, Hsinchu (TW); Chien Nan TU, Hsinchu (TW)

(73) Assignee: TAIWAN SEMICONDUCTOR MANUFACTURING COMPANY, LTD., Hsinchu (TW)

(21) Appl. No.: 18/680,621

(22) Filed: May 31, 2024

(51) Int. Cl. H01L 23/58; H01L 21/78; H01L 23/00; H01L 25/065

(52) U.S. Cl. CPC H01L 23/585; H01L 21/78; H01L 24/08; H01L 25/0657; H01L 2224/08145; H01L 2225/06541; H01L 2924/35121

(57) ABSTRACT

A semiconductor structure includes a first die and a second die. The first die includes a first semiconductor substrate, a first integrated circuit disposed on the first semiconductor substrate, and a first metal seal ring structure disposed on the first semiconductor substrate and surrounding the first integrated circuit. The second die includes a second semiconductor substrate, a second integrated circuit disposed on the second semiconductor substrate, and a second metal seal ring structure disposed on the second semiconductor substrate and surrounding the second integrated circuit. The second die is disposed over the first die, the second integrated circuit is electrically connected and bonded to the first integrated circuit, and the second metal seal ring structure is bonded to the first metal seal ring structure.

### BACKGROUND

In certain semiconductor processes to fabricate a stacked die, a die or a device wafer may be bonded to another wafer to create a wafer-level package. Subsequently, a wafer dicing process is conducted on the wafer-level package to obtain the stacked die.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram illustrating a top view of a wafer stack in accordance with some embodiments.

FIG. 2 is a sectional view of the wafer stack taken along line A-A in FIG. 1 in accordance with a first embodiment.

FIG. 3 is a sectional view illustrating a main circuit region of the wafer stack in accordance with some embodiments.

FIG. 4 is a sectional view illustrating an auxiliary circuit region of the wafer stack in accordance with some embodiments.

FIG. 5 is a sectional view illustrating a seal ring region of the wafer stack in accordance with the first embodiment.

FIG. 6 is a perspective view illustrating comparison between interconnection structures in the main/auxiliary circuit region and the seal ring region in accordance with some embodiments.

FIG. 7 is a sectional view illustrating a dicing region of the wafer stack in accordance with the some embodiments.

FIG. 8 is a sectional view of the wafer stack taken along line A-A in FIG. 1 in accordance with a second embodiment.

FIG. 9 is a sectional view illustrating a seal ring region of the wafer stack in accordance with the second embodiment.

FIGS. 10 to 15 are sectional views illustrating variants of the seal ring region of the wafer stack in accordance with the second embodiment.

FIGS. 16 and 17 are sectional views illustrating variants of the dicing region of the wafer stack in accordance with some embodiments.

FIG. 18 is a flow chart illustrating steps of a method for fabricating a stacked die in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

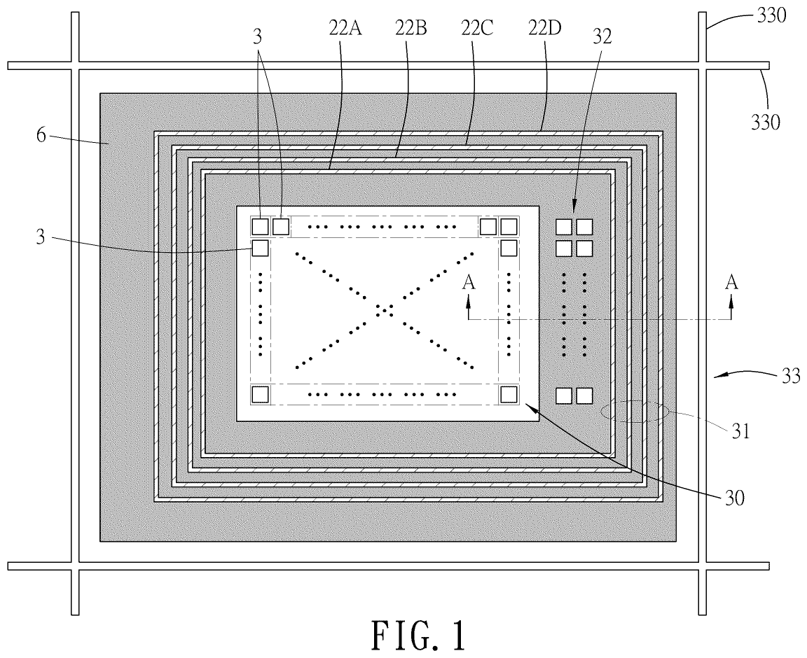

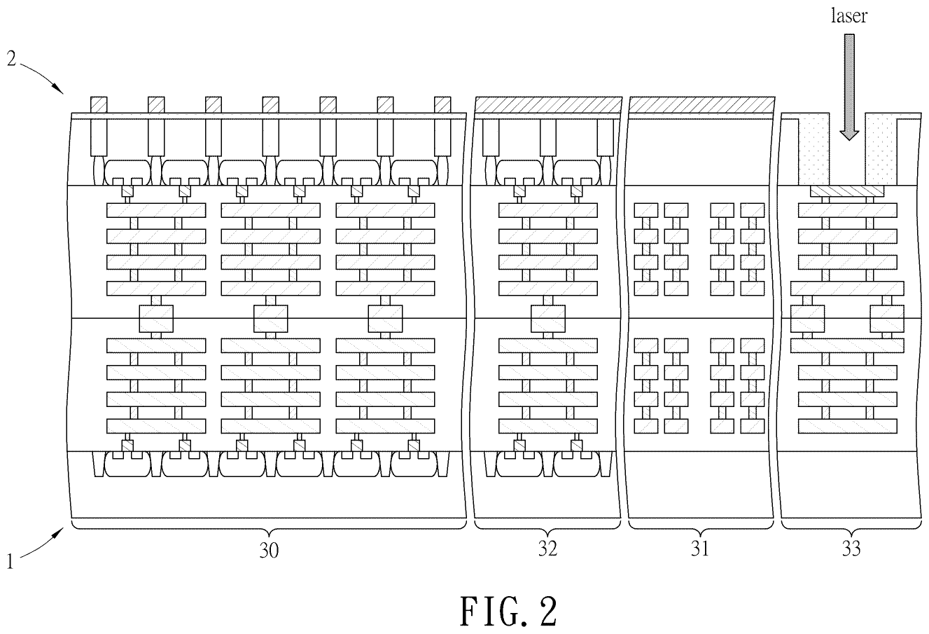

FIGS. 1 and 2 illustrate a wafer stack in accordance with a first embodiment. The wafer stack includes a first wafer that has a first die 1 formed on a front surface thereof, and a second wafer that has a second die 2 formed on a front surface thereof. Each of the first wafer and the second wafer may be made of a suitable semiconductor material, such as silicon or the like. In some embodiments, the first wafer and the second wafer are made of silicon; and in other embodiments, the first wafer and the second wafer may be made of a compound semiconductor such as silicon carbide, gallium arsenide, indium arsenide, indium phosphide or other suitable materials. In still other embodiments, the first wafer and the second wafer may be made of an alloy semiconductor such as GaAsP, AlInAs, AlGaAs, GaInAs, GaInP, GaInAsP or other suitable materials.

The first die 1 and the second die 2 are bonded together to form a semiconductor structure that has a main circuit region 30, a seal ring region 31 surrounding the main circuit region 30, an auxiliary circuit region 32 disposed between the main circuit region 30 and the seal ring region 31, and a dicing region 33 surrounding the seal ring region 31. From another point of view, it can be deemed that each of the first die 1 and the second die 2 has a main circuit region, a seal ring region, an auxiliary circuit region and a dicing region that correspond to the main circuit region 30, the seal ring region 31, the auxiliary circuit region 32 and the dicing region 33 of the semiconductor structure, respectively. The first die 1 includes a first main integrated circuit in the main circuit region 30, a first auxiliary integrated circuit in the auxiliary circuit region 32, and a first seal ring structure in the seal ring region 31. The second die 2 includes a second main integrated circuit in the main circuit region 30, a second auxiliary integrated circuit in the auxiliary circuit region 32, a second seal ring structure in the seal ring region 31, and a pattern of dicing channels in the dicing region 33. The pattern of dicing channels surrounds the seal ring region 31 when viewed from top. In the illustrative embodiment, the semiconductor structure is exemplified as a structure of CMOS image sensor, where the first die 1 is an application-specific integrated circuit (ASIC) for image data computation, and the second die 2 is a system-on-chip (SoC) that includes photosensing pixels for acquiring image data.

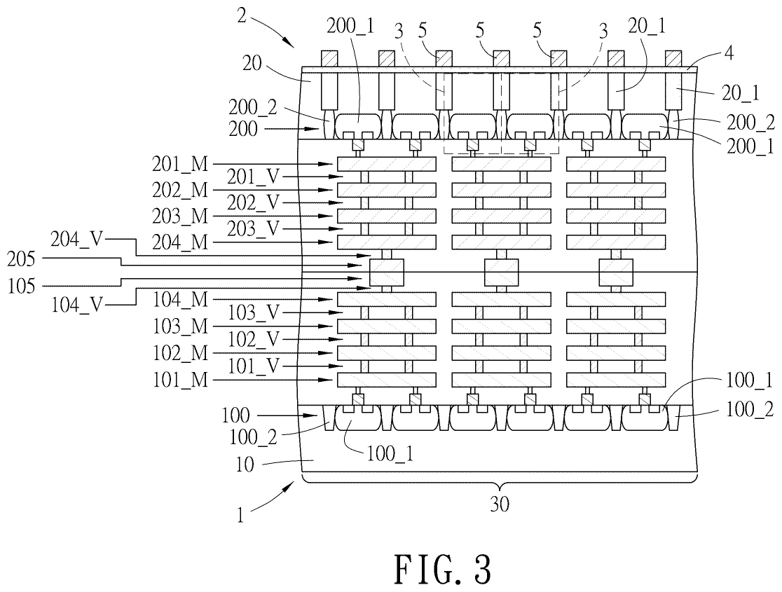

Further referring to FIG. 3, the first die 1 includes a first semiconductor substrate 10 (e.g., a part of the first wafer), a plurality of first interconnection layers stacked one on top the other on the first semiconductor substrate 10, and a first redistribution layer (RDL) covering the first interconnection layers. The first interconnection layers include a plurality of horizontal interconnection layers and a plurality of vertical interconnection layers that are stacked alternately. The second die 2 includes a second semiconductor substrate 20 (e.g., a part of the second wafer), a plurality of second interconnection layers stacked one on top the other on the second semiconductor substrate 20, and a second redistribution layer covering the second interconnection layers. The second interconnection layers include a plurality of horizontal interconnection layers and a plurality of vertical interconnection layers that are stacked alternately.

The first main integrated circuit includes a device layer 100 formed in the first semiconductor substrate 10, a first interconnection structure disposed in the first interconnection layers, and a first redistribution structure disposed in the first redistribution layer. The device layer 100 includes a plurality of semiconductor devices 100_1, and a plurality of isolation features 100_2 disposed among the semiconductor devices 100_1 for isolating the semiconductor devices 100_1 from each other. In the illustrative embodiment, the semiconductor devices 100_1 may include transistors and/or other circuit components, and the isolation features 100_2 may be shallow trench isolation (STI) features made of SiO₂, other dielectric materials, or any combination thereof. In some embodiments, the isolation features 100_2 may be doped with, for example, boron, other suitable elements, or any combination thereof, thereby preventing current leakage. The first interconnection structure is electrically connected to the semiconductor devices 100_1, and is exemplified to include a plurality of metal trench layers 101_M to 104_M and a plurality of metal via layers 101_V to 104_V. Each of the metal trench layers 101_M to 104_M is a part of a respective one of the horizontal interconnection layers of the first interconnection layers, and includes horizontally-spreading metal patterns (e.g., patterns formed by metal trenches that extend horizontally in multiple directions) formed therein. Each of the metal via layers 101_V to 104_V is a part of a respective one of the vertical interconnection layers of the first interconnection layers, and has vertically-extending metal features (e.g., metal vias that extend vertically) formed therein. The vertically-extending metal features in the metal via layers 101_V to 104_V interconnect the horizontally-spreading metal patterns in the metal trench layers 101_M to 104_M. The first redistribution structure is formed in a main redistribution circuit layer 105 that is a part of the first redistribution layer, and includes a plurality of redistribution metal features that are electrically connected to the first interconnection structure. It is noted that the terms “horizontal” and “vertical” make reference to a surface of the first semiconductor substrate 10, which is substantially parallel to a surface of the second semiconductor substrate 20. It is noted that a number of the first interconnection layers may vary in different embodiments, and is not limited to any embodiment of this disclosure.

The second main integrated circuit includes a device layer 200 formed in the second semiconductor substrate 20, a second interconnection structure disposed in the second interconnection layers, and a second redistribution structure disposed in the second redistribution layer. The device layer 200 includes a plurality of semiconductor components 200_1, and a plurality of isolation features 200_2 disposed among the semiconductor components 200_1 for isolating the semiconductor components 200_1 from each other. In the illustrative embodiment, the semiconductor components 200_1 may include, for example, photodiodes, transistors and/or other circuit components, and the isolation features 200_2 may be STI features made of SiO₂, other dielectric materials, or any combination thereof. In some embodiments, the isolation features 200_2 may be doped with, for example, boron, other suitable elements, or any combination thereof, thereby preventing current leakage. The semiconductor components 200_1 and the isolation features 200_2 cooperatively form a plurality of photosensing pixels 3 in the illustrative embodiment. The second interconnection structure is electrically connected to the semiconductor components 200_1, and is exemplified to include a plurality of metal trench layers 201_M to 204_M and a plurality of metal via layers 201_V to 204_V. Each of the metal trench layers 201_M to 204_M is a part of a respective one of the horizontal interconnection layers of the second interconnection layers, and has horizontally-spreading metal patterns formed therein. Each of the metal via layers 201_V to 204_V is a part of a respective one of the vertical interconnection layers of the second interconnection layers, and has vertically-extending metal features formed therein. The vertically-extending metal features in the metal via layers 201_V to 204_V interconnect the horizontally-spreading metal patterns in the metal trench layers 201_M to 204_M. The second redistribution structure is formed in a main redistribution circuit layer 205 that is a part of the second redistribution layer, and includes a plurality of redistribution metal features that are electrically connected to the second interconnection structure and that are bonded to the redistribution metal features in the main redistribution circuit layer 105, so the first main integrated circuit and the second main integrated circuit are electrically connected together. It is noted that a number of the second interconnection layers may vary in different embodiments, and is not limited to any embodiment of this disclosure.

Since the second die 2 of the illustrative embodiment is configured to receive light from a backside of the second semiconductor substrate 20, some optical structures are formed in a backside direction of the second die 2 relative to the photosensing pixels 3. In the illustrative embodiment, the optical structures include backside deep trench (BDT) features 20_1 in the second semiconductor substrate 20, and metal grids 5 on a backside surface of the second semiconductor substrate 20, but this disclosure is not limited to such. The BDT features 20_1 are disposed in the second semiconductor substrate 20 and aligned with the isolation features 200_2 vertically, and are configured to induce total internal reflection on light that enters the BDT features 20_1, so as to prevent optical interference between neighboring photosensing pixels 3. In some embodiments, the BDT features 20_1 may include, for example, SiO₂, other suitable materials, or any combination thereof. The metal grids 5 are aligned with the BDT features 20_1 vertically, and are configured to isolate the photosensing pixels 3 optically in order to prevent light leakage into neighboring photosensing pixels 3. In some embodiments, the metal grids 5 may include, for example, W, AlCu, Al, other suitable metal materials, or any combination thereof. In some embodiments, other optical structures may be formed to achieve desired optical properties, and this disclosure is not limited in this respect. In some embodiments where the second die 2 is not made to have optical functions, the optical structures may be omitted from the second die 2. In the illustrative embodiment, a protective layer 4 is formed between the second semiconductor substrate 20 and the metal grids 5, but this disclosure is not limited in this respect. The protective layer 4 may include, for example, SiO₂, other suitable materials, or any combination thereof.

Referring to FIGS. 2, 3 and 4, the first auxiliary integrated circuit in the auxiliary circuit region 32 has a similar circuit structure and a similar function as the first main integrated circuit in the main circuit region 30, and the second auxiliary integrated circuit in the auxiliary circuit region 32 has a similar circuit structure and a similar function as the second main integrated circuit in the main circuit region 30. In the illustrative embodiment, the auxiliary circuit region 32 is configured for black level calibration, and is formed with a plurality of the photosensing pixels 3 that are completely covered by a metal shield 6 in the backside direction of the second die 2. The metal shield 6 may be formed in the same layer as the metal grids 5, and is configured to block light from entering the photosensing pixels 3 in the auxiliary circuit region 32, so that the signals generated by the photosensing pixels 3 in the auxiliary circuit region 32 represent complete darkness and thus can be utilized for conducting black level calibration of the photosensing pixels 3 in the main circuit region 30. In some embodiments, the auxiliary circuit region 32 may be omitted.

In the illustrative embodiment, the first auxiliary integrated circuit includes a device layer 120 formed in the first semiconductor substrate 10, a first auxiliary interconnection structure disposed in the first interconnection layers, and a first auxiliary redistribution structure disposed in the first redistribution layer. The first auxiliary interconnection structure is electrically connected to semiconductor devices in the device layer 120, and is exemplified to include a plurality of metal trench layers 121_M to 124_M and a plurality of metal via layers 121_V to 124_V. Each of the metal trench layers 121_M to 124_M is a part of a respective one of the horizontal interconnection layers of the first interconnection layers, and includes horizontally-spreading metal patterns formed therein. Each of the metal via layers 121_V to 124_V is a part of a respective one of the vertical interconnection layers of the first interconnection layers, and has vertically-extending metal features formed therein. The vertically-extending metal features in the metal via layers 121_V to 124_V interconnect the horizontally-spreading metal patterns in the metal trench layers 121_M to 124_M. The first auxiliary redistribution structure is formed in an auxiliary redistribution circuit layer 125 that is a part of the first redistribution layer, and includes a plurality of redistribution metal features that are electrically connected to the first auxiliary interconnection structure.

The second auxiliary integrated circuit includes a device layer 220 formed in the second semiconductor substrate 20, a second auxiliary interconnection structure disposed in the second interconnection layers, and a second auxiliary redistribution structure disposed in the second redistribution layer. The device layer 220 includes a plurality of photosensing pixels 3 formed therein. The second auxiliary interconnection structure is electrically connected to the photosensing pixels 3 of the device layer 220, and is exemplified to include a plurality of metal trench layers 221_M to 224_M and a plurality of metal via layers 221_V to 224_V. Each of the metal trench layers 221_M to 224_M is a part of a respective one of the horizontal interconnection layers of the second interconnection layers, and has horizontally-spreading metal patterns formed therein. Each of the metal via layers 221_V to 224_V is a part of a respective one of the vertical interconnection layers of the second interconnection layers, and has vertically-extending metal features formed therein. The vertically-extending metal features in the metal via layers 221_V to 224_V interconnect the horizontally-spreading metal patterns in the metal trench layers 221_M to 224_M. The second auxiliary redistribution structure is formed in an auxiliary redistribution circuit layer 225 that is a part of the second redistribution layer, and includes a plurality of redistribution metal features that are electrically connected to the second auxiliary interconnection structure and that are bonded to the redistribution metal features of the first auxiliary redistribution structure, so the first auxiliary integrated circuit and the second auxiliary integrated circuit are electrically connected together.

Referring to FIGS. 1, 2 and 5, in the seal ring region 31, the first seal ring structure of the first die 1 includes a plurality of metal trench layers 111_M to 114_M, and a plurality of metal via layers 111_V to 113_V. Each of the metal trench layers 111_M to 114_M is a part of a respective one of the horizontal interconnection layers of the first interconnection layers. Each of the metal via layers 111_V to 114_V is a part of a respective one of the vertical interconnection layers of the first interconnection layers. The first seal ring structure has at least one seal ring group formed in the metal trench layers 111_M to 114_M and the metal via layers 111_V to 114_V. In the illustrative embodiment, the first seal ring structure is exemplified to include inner seal ring groups 12A, 12B and outer seal ring groups 12C, 12D. The inner seal ring groups 12A, 12B are closer to the main circuit region 30 and the auxiliary circuit region 32 in comparison to the outer seal ring groups 12C, 12D. In some embodiments, the outer seal ring groups 12C, 12D are adjacent to the inner seal ring groups 12A, 12B. In some embodiments, the outer seal ring groups 12C, 12D are distant from the inner seal ring groups 12A, 12B, or additional structures may be formed between the inner seal ring groups 12A, 12B and the outer seal ring groups 12C, 12D, and this disclosure is not limited in this respect. Each of the seal ring groups 12A to 12D includes a plurality of first interconnection-layer seal rings disposed in the metal trench layers 111_M to 114_M and the metal via layers 111_V to 114_V, where the first interconnection-layer seal rings overlap or are aligned with each other vertically. Each of the first interconnection-layer seal rings surrounds the first interconnection structure in the main circuit region 30 and the first auxiliary interconnection structure in the auxiliary circuit region 32, and is connected to the first interconnection-layer seal ring(s) of the same seal ring group in adjacent first interconnection layer(s). In the illustrative embodiment, each of the seal ring groups 12A to 12D includes a first interconnection-layer seal ring in each of the metal trench layers 111_M to 114_M and the metal via layers 111_V to 114_V, but this disclosure is not limited in this respect. It is noted that the word “ring” in the term “seal ring” does not imply a circular shape. The term “seal ring” is a commonly used term in the semiconductor industry, and a seal ring is often made in a rectangular shape. However, this disclosure is not limited in this respect.

The second seal ring structure of the second die 2 includes a plurality of metal trench layers 211_M to 214_M, and a plurality of metal via layers 211_V to 213_V. Each of the metal trench layers 211_M to 214_M is a part of a respective one of the horizontal interconnection layers of the second interconnection layers. Each of the metal via layers 211_V to 214_V is a part of a respective one of the vertical interconnection layers of the second interconnection layers. The second seal ring structure has at least one seal ring group formed in the metal trench layers 211_M to 214_M and the metal via layers 211_V to 214_V. In the illustrative embodiment, the second seal ring structure is exemplified to include inner seal ring groups 22A, 22B and outer seal ring groups 22C, 22D. The inner seal ring groups 22A, 22B are closer to the main circuit region 30 and the auxiliary circuit region 32 in comparison to the outer seal ring groups 22C, 22D. In some embodiments, the outer seal ring groups 22C, 22D are adjacent to the inner seal ring groups 22A, 22B. In some embodiments, the outer seal ring groups 22C, 22D are distant from the inner seal ring groups 22A, 22B, or additional structures may be formed between the inner seal ring groups 22A, 22B and the outer seal ring groups 22C, 22D, and this disclosure is not limited in this respect. In the illustrative embodiment, the seal ring groups 22A to 22D are vertically aligned with the seal ring groups 12A to 12D, respectively. Each of the seal ring groups 22A to 22D includes a plurality of second interconnection-layer seal rings disposed in the metal trench layers 211_M to 214_M and the metal via layers 211_V to 214_V, where the second interconnection-layer seal rings overlap or are aligned with each other vertically. Each of the second interconnection-layer seal rings surrounds the second interconnection structure in the main circuit region 30 and the second auxiliary interconnection structure in the auxiliary circuit region 32. In the illustrative embodiment, each of the seal ring groups 22A to 22D includes a second interconnection-layer seal ring in each of the metal trench layers 211_M to 214_M and the metal via layers 211_V to 214_V, but this disclosure is not limited in this respect. In accordance with some embodiments, each of the first interconnection-layer seal rings and the second interconnection-layer seal rings is made of the same metal material(s) as used in the same layer of the main integrated circuit and the auxiliary integrated circuit. In accordance with some embodiments, each of the first interconnection-layer seal rings and the second interconnection-layer seal rings is made of one or more metal materials that are different from the metal material(s) used in the same layer of the main integrated circuit and the auxiliary integrated circuit.

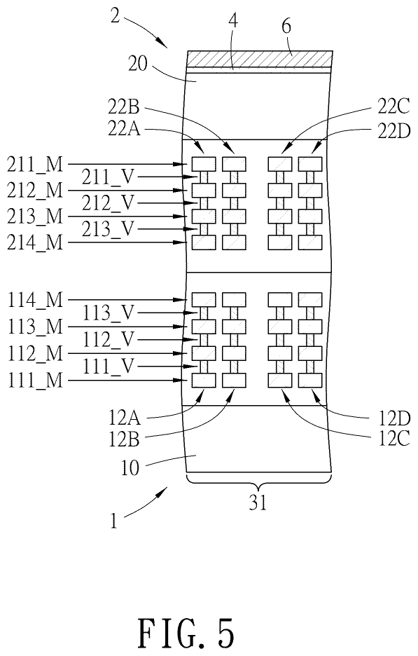

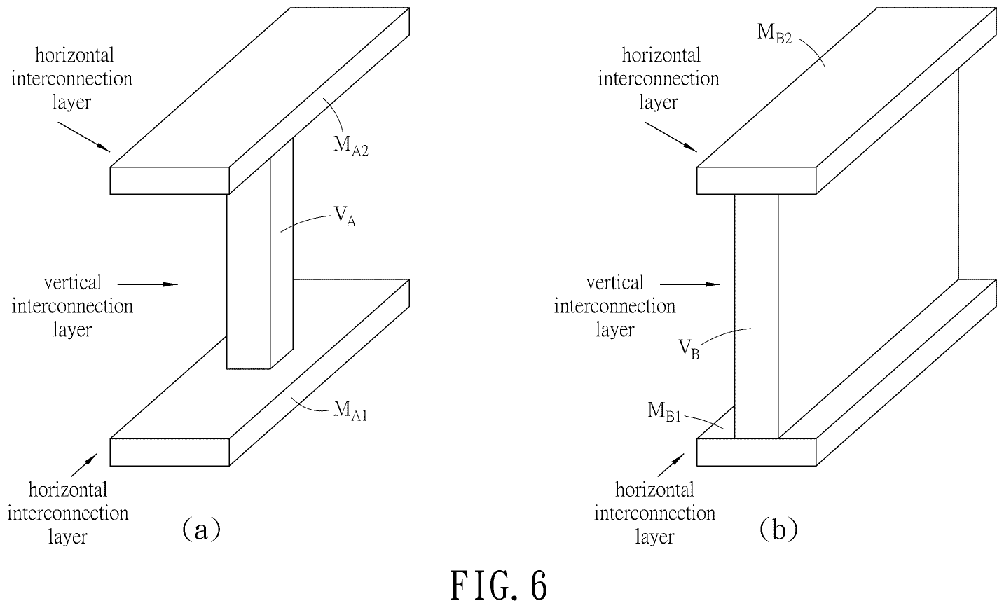

Referring to FIG. 6, part (a) exemplarily illustrates a metal via V_{A} that is in one of the vertical interconnection layers in the main circuit region 30 or the auxiliary circuit region 32 (see FIG. 2) and that interconnects two metal trenches M_{A1}, M_{A2} respectively in neighboring horizontal interconnection layers, while part (b) exemplarily illustrates an interconnection-layer seal ring V_{B} that is in one of the vertical interconnection layers in the seal ring region 31 (see FIG. 2) and that interconnects two interconnection-layer seal rings M_{B1}, M_{B2} respectively in neighboring horizontal interconnection layers. The interconnection-layer seal ring V_{B} is different from the metal via V_{A} in that the interconnection-layer seal ring V_{B} extends not only vertically to interconnect the interconnection-layer seal rings M_{B1}, M_{B2}, but also horizontally, thereby aligning with an extending direction (e.g., into the page of FIG. 5) of the interconnection-layer seal rings M_{B1}, M_{B2}, thereby cooperating with the interconnection-layer seal rings M_{B1}, M_{B2} to form a metal wall. Unlike the metal via V_{A} which is configured for enabling signal transmission between the metal trenches M_{A1}, M_{A2}, the interconnection-layer seal rings V_{B}, M_{B1}, M_{B2} are configured to, after the wafer stack is diced into stacked dies, prevent moisture from entering the corresponding integrated circuits that are surrounded by the interconnection-layer seal rings V_{B}, M_{B1}, M_{B2} from the edges of the corresponding stacked die.

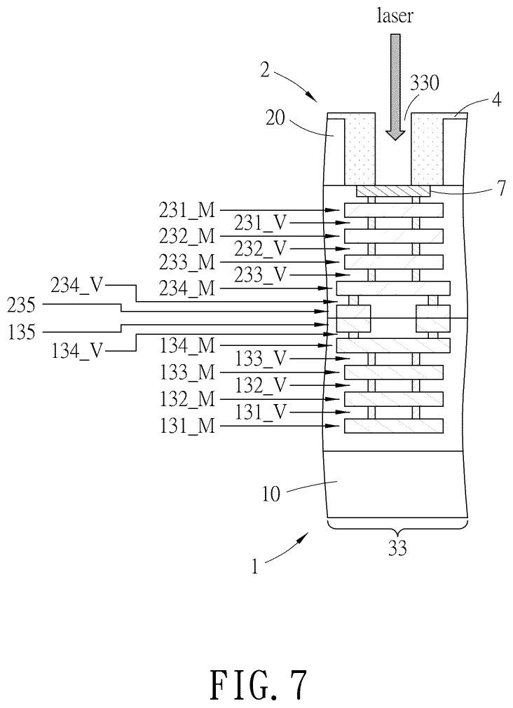

Referring to FIGS. 1 and 7, the dicing region 33 is configured for laser grooving and/or wafer sawing to dice the wafer stack into multiple stacked dies. In the illustrative embodiment, the first wafer and the second wafer are configured to include an inspection circuit electrically connected to the main integrated circuits and the auxiliary integrated circuits, so the main integrated circuits and the auxiliary integrated circuits can be inspected at a production line through the inspection circuit before wafer dicing, but this disclosure is not limited in this respect. In some embodiments, the inspection circuit may be omitted. It is noted that, in order to enable electrical connections from the inspection circuit in the dicing region 33 to the main integrated circuits and the auxiliary integrated circuits respectively in the main circuit region 30 and the auxiliary circuit region 32, the interconnection-layer seal rings in the seal ring region 31 may not seamlessly enclose the main integrated circuits and the auxiliary integrated circuits, and may be formed with some openings so that signal lines can pass through the seal ring region 31 and establish connections between the inspection circuit and the integrated circuits.

In the illustrative embodiment, the inspection circuit includes a first part and a second part respectively on the first wafer and the second wafer. The first part of the inspection circuit is formed in multiple metal trench layers 131_M to 134_M, multiple metal via layers 131_V to 134_V, and a redistribution layer 135 on the first wafer. The second part of the inspection circuit is formed in multiple metal trench layers 231_M to 234_M, multiple metal via layers 231_V to 234_V, and a redistribution layer 235 on the second wafer. Each of the metal trench layers 131_M to 134_M is an extension of a respective one of the horizontal interconnection layers of the first interconnection layers of the first die 1, and has horizontally-spreading metal patterns formed therein. Each of the metal via layers 131_V to 134_V is an extension of a respective one of the vertical interconnection layers of the first interconnection layers of the first die 1, and has vertically-extending metal features formed therein. The redistribution layer 135 is an extension of the first redistribution layer of the first die 1, and includes redistribution metal features formed therein. Each of the metal trench layers 231_M to 234_M is an extension of a respective one of the horizontal interconnection layers of the second interconnection layers of the second die 2, and has horizontally-spreading metal patterns formed therein. Each of the metal via layers 231_V to 234_V is an extension of a respective one of the vertical interconnection layers of the second interconnection layers of the second die 2, and has vertically-extending metal features formed therein. The redistribution layer 235 is an extension of the second redistribution layer of the second die 2, and includes redistribution metal features formed therein. The redistribution metal features in the redistribution layer 135 are bonded to the redistribution metal features in the redistribution layer 235, so the first part and the second part of the inspection circuit are electrically connected together. A contact pad 7 is formed to be electrically connected to the second part of the inspection circuit and is exposed from a recess 330 that serves as a dicing channel in the illustrative embodiment, so signals from the inspection circuit can be measured through the contact pad 7 using, for example, a probe. The dicing channel 330 is configured for laser grooving and/or wafer sawing, and helps to define edges of the first die 1 and the second die 2 when the first die 1 and the second die 2 are formed after wafer dicing.

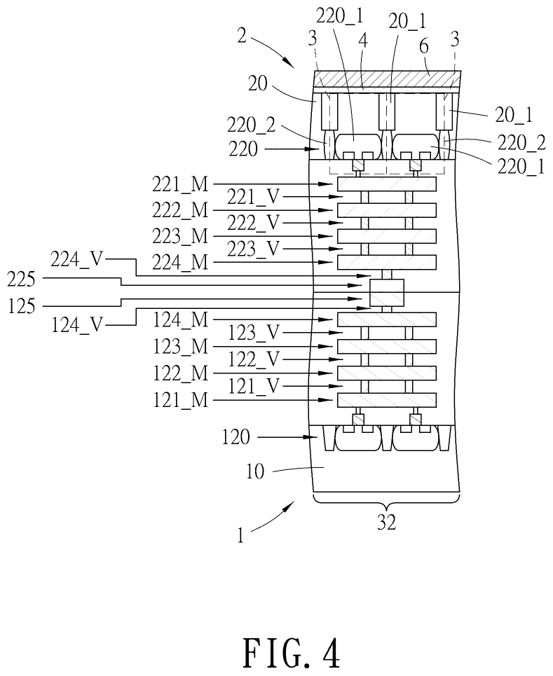

Referring to FIGS. 1, 8 and 9, a semiconductor structure is illustrated in accordance with a second embodiment. The second embodiment is similar to the first embodiment, and in the second embodiment, the first seal ring structure of the first die 1 further includes a first RDL seal ring layer 115 that is a part of the first redistribution layer of the first die 1, and second seal ring structure of the second die 2 further includes a second RDL seal ring layer 215 that is a part of the second redistribution layer of the second die 2. Each of the seal ring groups 12A to 12D further includes a first RDL seal ring formed in the first RDL seal ring layer 115. The first RDL seal ring surrounds the first redistribution structure in the main redistribution circuit layer 105 (see FIG. 3) and the first auxiliary redistribution structure in the auxiliary redistribution circuit layer 125 (see FIG. 4), is vertically aligned with the first interconnection-layer seal rings of the corresponding one of the seal ring groups 12A to 12D, and is electrically connected to at least one of the first interconnection-layer seal rings of the corresponding one of the seal ring groups 12A to 12D. Similarly, each of the seal ring groups 22A to 22D further includes a second RDL seal ring formed in the second RDL seal ring layer 215. The second RDL seal ring surrounds the second redistribution structure in the main redistribution circuit layer 205 (see FIG. 3) and the second auxiliary redistribution structure 225 in the auxiliary redistribution circuit layer 125 (see FIG. 4), is vertically aligned with the second interconnection-layer seal rings of the corresponding one of the seal ring groups 22A to 22D, and is electrically connected to at least one of the second interconnection-layer seal rings of the corresponding one of the seal ring groups 22A to 22D. The first RDL seal rings of the seal ring groups 12A to 12D are vertically aligned with and bonded to the second RDL seal rings of the seal ring groups 22A to 22D, respectively. In accordance with some embodiments, each of the first RDL seal rings and the second RDL seal rings is made of the same metal material(s) as used in the same layer (e.g., the first redistribution layer or the second redistribution layer) of the main integrated circuit and the auxiliary integrated circuit. In accordance with some embodiments, each of the first RDL seal rings and the second RDL seal rings is made of one or more different metal materials from the metal material(s) used in the same layer of the main integrated circuit and the auxiliary integrated circuit.

Since the first RDL seal rings and the second RDL seal rings are bonded together at an interface between the first wafer and the second wafer and have vertical connections to the first and second interconnection-layer seal rings, when the laser grooving or wafer sawing is performed on the dicing region 32, stress that propagates horizontally along the interface may be guided toward vertical directions (e.g., downward to the first semiconductor substrate 10 and/or upward to the second semiconductor substrate 20), thereby alleviating stress that propagates into the main circuit region 30 and the auxiliary circuit region 32. As a result, probability of delamination occurring in the main circuit region 30 and/or the auxiliary circuit region 32 may decrease, thereby improving production yield.

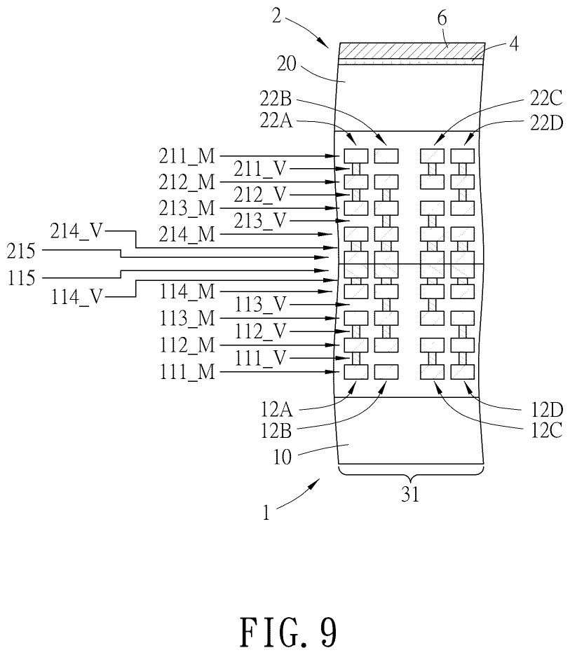

In the illustrative embodiment, for each of the seal ring groups 12A to 12D, the first interconnection-layer seal rings are not present in every single one of the metal trench layers 111_M to 114_M and the metal via layers 111_V to 114_V. In other words, the first interconnection-layer seal rings of each of the seal ring groups 12A to 12D are divided into at least two sub-groups that are electrically isolated from each other by one or more dielectric segments of one or more of the metal trench layers 111_M to 114_M and the metal via layers 111_V to 114_V, and the first RDL seal ring is electrically connected only to the nearest sub-group. For example, for the seal ring group 12A, the first RDL seal ring is electrically connected only to the first interconnection-layer seal rings in the metal via layer 114_V and the metal trench layer 114_M, and is electrically isolated from the first interconnection-layer seal rings in the metal via layers 111_V and 112_V and the metal trench layers 111_M to 113_M by the metal via layer 113_V. Similarly, for each of the seal ring groups 22A to 22D, the second interconnection-layer seal rings are not present in every single one of the metal trench layers 211_M to 214_M and the metal via layers 211_V to 214_V. In other words, the second interconnection-layer seal rings of each of the seal ring groups 22A to 22D are divided into at least two sub-groups that are electrically isolated from each other by one or more dielectric segments of one or more of the metal trench layers 211_M to 214_M and the metal via layers 211_V to 214_V, and the second RDL seal ring is electrically connected only to the nearest sub-group. For example, for the seal ring group 12A, the second RDL seal ring is electrically connected only to the second interconnection-layer seal rings in the metal via layer 214_V and the metal trench layer 214_M, and is electrically isolated from the second interconnection-layer seal rings in the metal via layers 211_V and 212_V and the metal trench layers 211_M to 213_M by the metal via layer 213_V. Such configuration is made to reduce undesired flow of electric charges between the seal rings in the first wafer and the seal rings in the second wafer, which may impact operations of the integrated circuits in the main circuit region 30 and the auxiliary circuit region 32. In this embodiment, conducting paths between the first wafer and the second wafer in the seal ring region 31 are shortened by dividing each of the seal ring groups 12A to 12D and 22A to 22D into multiple sub-groups that are electrically isolated from each other, thereby reducing the abovementioned concerns. However, for each of the seal ring groups 12A to 12D and 22A to 22D, a lack of the interconnection-layer seal ring in one or more of the metal trench layers and the metal via layers may deteriorate the ability of the seal ring group in resisting moisture. In order to minimize such impact, for adjacent two of the seal ring groups 12A to 12D or 22A to 22D, if, for one metal trench layer or metal via layer, one seal ring group does not have an interconnection-layer seal ring therein, then the other seal ring group is made to have an interconnection-layer seal ring in that metal trench layer or metal via layer, while at the same time, said the other seal ring group would not have an interconnection-layer seal ring in another metal trench layer or metal via layer, thereby preventing moisture from easily passing through the two seal ring groups. As a result, if one of the metal trench layers and the metal via layers electrically isolates the RDL seal ring from one or more interconnection-layer seal rings in one seal ring group, there would be another one of the metal trench layers and the metal via layers that electrically isolates the RDL seal ring from one or more interconnection-layer seal rings in an adjacent seal ring group. For example, in FIG. 9, only the metal trench layer 113_V does not have any of the first interconnection-layer seal rings of the seal ring group 12A, and only the metal via layer 111_V does not have any of the first interconnection-layer seal rings of the seal ring group 12B, which is horizontally adjacent to the seal ring group 12A. As a result, in this example, the metal via layer 113_V electrically isolates the first interconnection-layer seal rings of the seal ring group 12A in the layers 111_M to 113_M and 111_V to 112_V from the first RDL seal ring of the seal ring group 12A, and another metal via layer 111_V electrically isolates the first interconnection-layer seal ring of the seal ring group 12B in the metal trench layer 111_M from the first RDL seal ring of the seal ring group 12B.

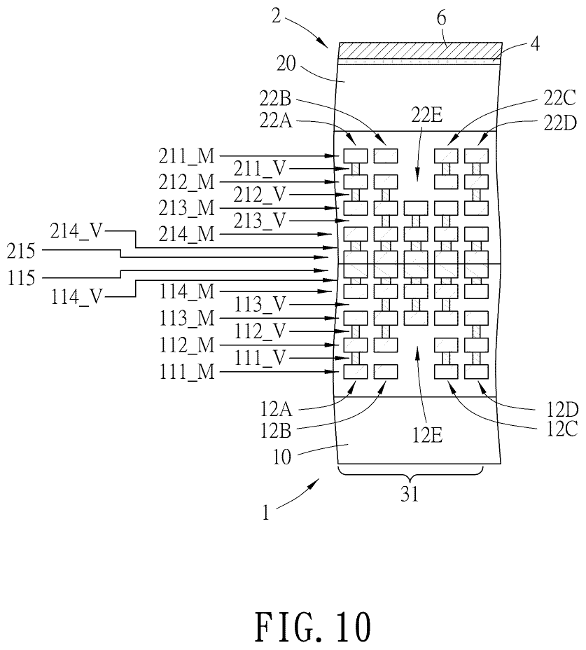

Referring to FIG. 10, a variant of the seal ring groups 12A to 12D and 22A to 22D is illustrated in accordance with some embodiments. This variant is similar to the first embodiment as shown in FIG. 9, and differs in that, in this variant, the first seal ring structure of the first die 1 and the second seal ring structure of the second die 2 further include a seal ring group 12E and a seal ring group 22E, respectively, where the seal ring group 12E is aligned with the seal ring group 22E vertically. The seal ring group 12E has fewer first interconnection-layer seal rings than the seal ring groups 12A to 12D in the first interconnection layers, and has a first RDL seal ring in the first redistribution layer. The first RDL seal ring is vertically aligned with and electrically connected to all of the first interconnection-layer seal rings of the seal ring group 12E. Similarly, the seal ring group 22E has fewer second interconnection-layer seal rings than the seal ring groups 22A to 22D in the second interconnection layers, and has a second RDL seal ring in the second redistribution layer. The second RDL seal ring is vertically aligned with and electrically connected to all of the second interconnection-layer seal rings of the seal ring group 22E. The second RDL seal ring of the seal ring group 22E is bonded to the first RDL seal ring of the seal ring group 12E. Due to this configuration, the overall length of each of the seal ring groups 12E, 22E is smaller than the overall length of each of the other seal ring groups 12A to 12D and 22D to 22D. As a result, there is less of a concern of flow of electric charges between the first wafer and the second wafer through the seal ring groups 12E, 22E, and hence less need to divide the seal ring groups 12E, 22E into multiple electrically isolated sub-groups. In accordance with some embodiments, the seal ring group 12E is disposed between two of the seal ring groups 12A to 12D, and the seal ring group 22E is disposed between two of the seal ring groups 22A to 22D. In accordance with some embodiments, a number of the first interconnection-layer seal rings in the seal ring group 12E is not greater than half of a number of the first interconnection layers, and a number of the second interconnection-layer seal rings in the seal ring group 22E is not greater than half of a number of the second interconnection layers. That is, at most the top half of the first interconnection layers have the first interconnection-layer seal rings formed therein as the seal ring group 12E, and at most the top half of the second interconnection layers have the second interconnection-layer seal rings formed therein as the seal ring group 22E. These additional seal ring groups 12E and 22E may further assist in diverting the stress of laser grooving or wafer sawing from horizontal propagation into vertical propagation, thereby further reducing the probability of delamination occurring in the main circuit region 30 and/or the auxiliary circuit region 32.

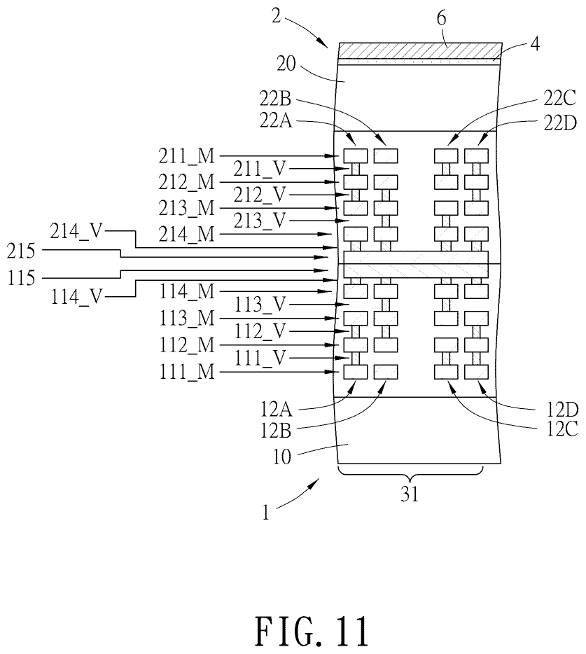

Referring to FIG. 11, a variant of the seal ring groups 12A to 12D and 22A to 22D is illustrated in accordance with some embodiments. This variant is similar to the second embodiment as shown in FIG. 9, and differs in that, in this variant, the first RDL seal rings of the seal ring groups 12A to 12D are formed in one piece, and the second RDL seal rings of the seal ring groups 22A to 22D are formed in one piece. In accordance with some embodiments, it may be that only the first RDL seal rings of the seal ring groups 12A to 12D or only the second RDL seal rings of the seal ring groups 22A to 22D are formed in one piece. In accordance with some embodiments, it may be that only some of the first RDL seal rings of the seal ring groups 12A to 12D and/or only some of the second RDL seal rings of the seal ring groups 22A to 22D are formed in one piece. Such configuration may lead to stronger bonding between the seal ring groups 12A to 12D in the first wafer and the seal ring groups 22A to 22D in the second wafer, so as to reduce the probability of delamination occurring in the seal ring region 31.

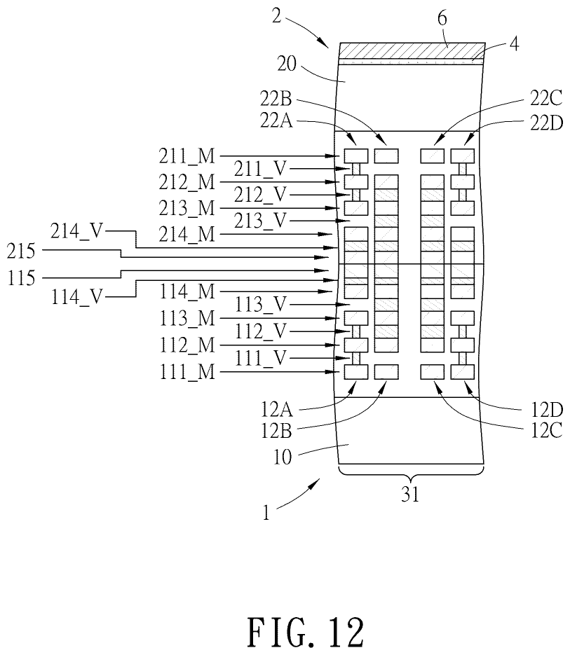

Referring to FIG. 12, a variant of the seal ring groups 12A to 12D and 22A to 22D is illustrated in accordance with some embodiments. This variant is similar to the second embodiment as shown in FIG. 9, and differs in that, in this variant, contrary to the metal vias being usually narrower than the metal trenches in the main circuit region 30 and the auxiliary circuit region 32 (see FIG. 2), the interconnection-layer seal rings in the vertical interconnection layers may have either the same or greater widths than the interconnection-layer seal rings in the horizontal interconnection layers. In FIG. 11, for each of the seal ring groups 12B, 12C, 22B and 22C, the interconnection-layer seal rings in the vertical interconnection layers (e.g., the metal via layers 112_V to 114_V and 212_V to 214_V) have substantially the same width as the interconnection-layer seal rings in the horizontal interconnection layers (e.g., the metal trench layers 111_M to 114_M and 211_M to 214_M). On the other hand, for each of the seal ring groups 12A, 12D, 22A and 22D, the interconnection-layer seal rings in some vertical interconnection layers (e.g., the metal via layers 111_V, 112_V, 211_V and 212_V) are narrower than the interconnection-layer seal rings in the horizontal interconnection layers, while the interconnection-layer seal rings in the metal via layers 114_V, 214_V have substantially the same width as the interconnection-layer seal rings in the horizontal interconnection layers. Wider seal rings in the vertical interconnection layers may enhance the ability of the seal ring structures in resisting moisture, making the entire semiconductor structure more reliable.

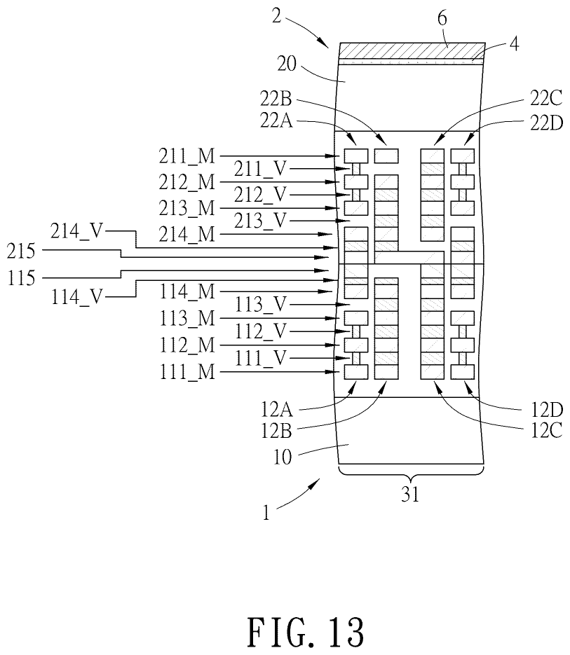

Referring to FIG. 13, a variant of the seal ring groups 12A to 12D and 22A to 22D is illustrated in accordance with some embodiments. This variant is similar to the variant as shown in FIG. 11, and differs mainly in that, in this variant, only the second RDL seal rings in the seal ring groups 22B and 22C are formed in one piece, so the second RDL seal ring in the seal ring group 22B is electrically connected to the first RDL seal ring in the seal ring group 12C. The seal ring group 12B does not include a seal ring in the first RDL seal ring layer 115. In the seal ring group 22C, the second interconnection-layer seal rings are not connected to the second RDL seal ring. From another point of view, the second RDL seal ring in the seal ring group 22B extends horizontally to overlap the second interconnection-layer seal rings of the seal ring group 22C, and is bonded to the first RDL seal ring of the seal ring group 12C. From yet another point of view, the first interconnection-layer seal rings in the seal ring group 12C are electrically connected to the second RDL seal ring of the seal ring group 22C, which is misaligned vertically with the first interconnection-layer seal rings in the seal ring group 12C. In some embodiments, it can be that the first RDL seal ring of the seal ring group 12C extends horizontally to overlap the first interconnection-layer seal rings of the seal ring group 12B and thus the first RDL seal ring of the seal ring group 12C is bonded to the second RDL seal ring of the seal ring group 22B, which may achieve a similar effect as the configuration shown in FIG. 13. Such a configuration may prevent the horizontally-propagating stress from being directed to opposite vertical directions at the same point of the interface between the first wafer and the second wafer, so as to reduce the probability of delamination occurring in the seal ring region 31. For example, in FIG. 13, the stress may be directed downward at the interface between the first RDL seal ring of the seal ring group 12C and the second RDL seal ring of the seal ring group 22C, and then directed upward through the seal ring group 22B.

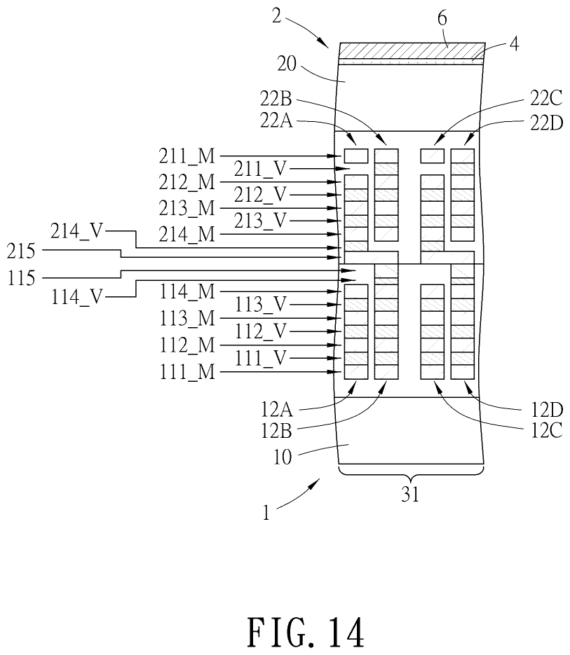

Referring to FIG. 14, a variant of the seal ring groups 12A to 12D and 22A to 22D is illustrated in accordance with some embodiments. This variant is similar to the variant as shown in FIG. 13, and differs in that the configuration of the seal ring groups 12B, 12C, 22B, 22C in FIG. 13 are applied to the inner seal ring groups 12A, 12B, 22A, 22B and the outer seal ring groups 12C, 12D, 22C, 22D in this variant. In a case where the inner seal ring groups 12A, 12B, 22A, 22B are distant from the outer seal ring groups 12C, 12D, 22C, 22D or additional structures are formed between the inner seal ring groups 12A, 12B, 22A, 22B and the outer seal ring groups 12C, 12D, 22C, 22D, the configuration illustrated in FIG. 13 may not be applicable, but this variant may apply.

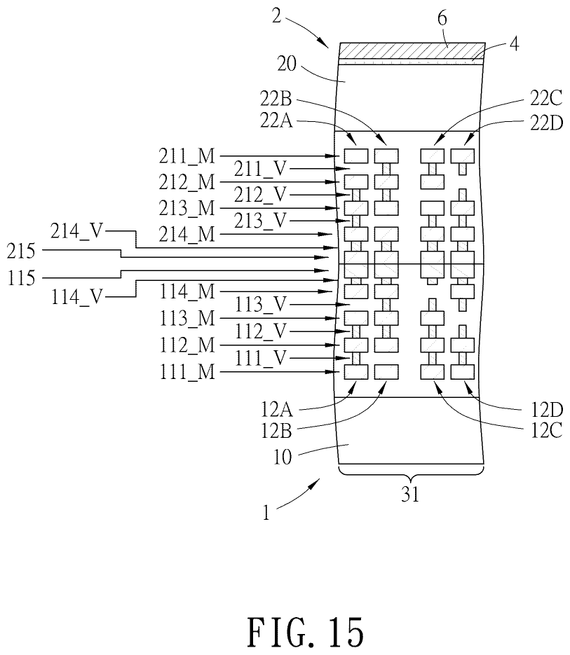

Referring to FIG. 15, a variant of the seal ring groups 12A to 12D and 22A to 22D is illustrated in accordance with some embodiments. This variant is similar to the second embodiment as shown in FIG. 9. In this variant, for each pair of the vertically-aligned seal ring groups (i.e., the seal ring groups 12A and 22A, the seal ring groups 12B and 22B, the seal ring groups 12C and 22C, and the seal ring groups 12D and 22D in FIG. 15), the RDL seal ring of one seal ring group is electrically connected to more than half of the interconnection-layer seal rings of that seal ring group, and the RDL seal ring of the other seal ring group is electrically connected to fewer than half of the interconnection-layer seal rings of said the other seal ring group. Taking the seal ring groups 12A and 22A as an example, the first RDL seal ring in the seal ring group 12A is electrically connected to two out of seven first interconnection-layer seal rings (i.e., electrically connected only to the first interconnection-layer seal rings in the layers 114_M and 114_V, and electrically isolated from the first interconnection-layer seal rings in the layers 111_M to 113_M and 111_V to 112_V), and the second RDL seal ring in the seal ring group 22A is electrically connected to six out of seven second interconnection-layer seal rings (i.e., electrically connected to the second interconnection-layer seal rings in the layers 212_M to 214M and 212_V to 214_V, and electrically isolated from the second interconnection-layer seal ring in the layer 211_M). By virtue of such configuration, the horizontally-propagating stress can be guided vertically, deep into one of the first wafer and the second wafer (e.g., along a path from the second RDL seal ring to the second interconnection-layer seal ring in the metal trench layer 212_M for the seal ring group 22A in FIG. 15), thereby effectively reducing the stress that may enter the main circuit region 30 and/or the auxiliary circuit region 32. Meanwhile, because the RDL seal ring in the other wafer is connected to only a few interconnection-layer seal rings of the same seal ring group, the impact resulting from the flow of electric charges between the two wafers may be reduced. For example, in FIG. 15, the probability of the integrated circuits in the first wafer being affected by the flow of electric charges in the seal ring groups 12A and 22A may be small because the electric charges in the seal ring group 22A is unable to reach a position that is deep in the first wafer; and the probability of the integrated circuits in the second wafer being affected may be small as well because only the first interconnection-layer seal rings in the layers 114_M and 114_V are electrically connected to the seal ring group 22A, which allows only a few electric charges in the seal ring group 12A to flow into the second wafer.

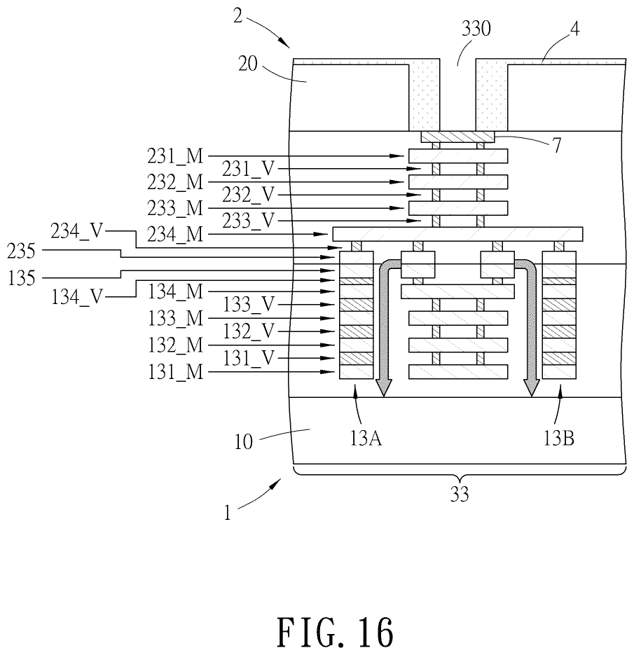

Referring to FIG. 16, a variant of the dicing region 33 is illustrated in accordance with some embodiments. This variant is similar to the first embodiment as shown in FIG. 7, and differs in that, in this variant, the dicing region 33 further includes a pair of stress guiding features 13A, 13B formed in the first wafer at two opposite sides of the dicing channel 330 when viewed from the top. Each of the stress guiding features 13A, 13B includes first interconnection-layer metal features disposed in the metal trench layers 131_M to 134_M and the metal via layers 131_V to 134_V, and a first RDL metal feature disposed in the redistribution layer 135 and electrically connected to the first interconnection-layer metal features of the same stress guiding feature. The first interconnection-layer metal features are connected to each other, and are vertically aligned with the first RDL metal feature of the same stress guiding feature. The second wafer includes two second RDL metal features in the redistribution layer 235, and the second RDL metal features are bonded respectively to the first RDL metal features of the stress guiding features 13A, 13B. In some embodiments, the first interconnection-layer metal features, the first RDL metal features and the second RDL metal features may be metal strips that extend linearly and horizontally (e.g., into the page of FIG. 16) along the dicing channel 330, and the combined the first interconnection-layer metal features and the first RDL metal feature form a metal wall that extends linearly along the dicing channel 330 and that can further prevent moisture from entering inner portions of the first die 1 after the wafer stack is diced into stacked dies. In some embodiments, the first interconnection-layer metal features, the first RDL metal features and the second RDL metal features may be metal rings that surround the main integrated circuits and the auxiliary integrated circuits like the seal rings in the seal ring region 31. The combination of the stress guiding features 13A, 13B and the second RDL metal features can, like the seal ring groups in the seal ring region 31, divert the stress of laser grooving or wafer sawing from horizontal propagation into vertical propagation (see the arrows in FIG. 16), thereby further reducing the probability of delamination occurring in the main circuit region 30 and/or the auxiliary circuit region 32. In the illustrative embodiment, the stress guiding features 13A, 13B are electrically connected to the inspection circuit. In some embodiments, the stress guiding features 13A, 13B and the second RDL metal features may be made separately or electrically independent from the inspection circuit, and the same effect can be achieved. In some embodiments, the inspection circuit may be omitted, but the stress guiding features 13A, 13B and the second RDL metal features can still be made to have a similar configuration to achieve the same effect.

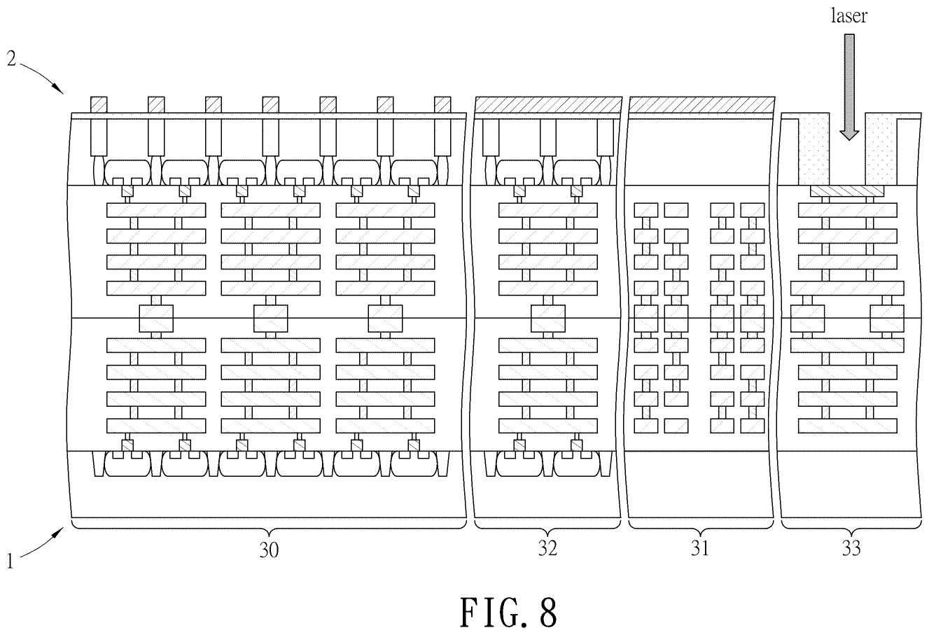

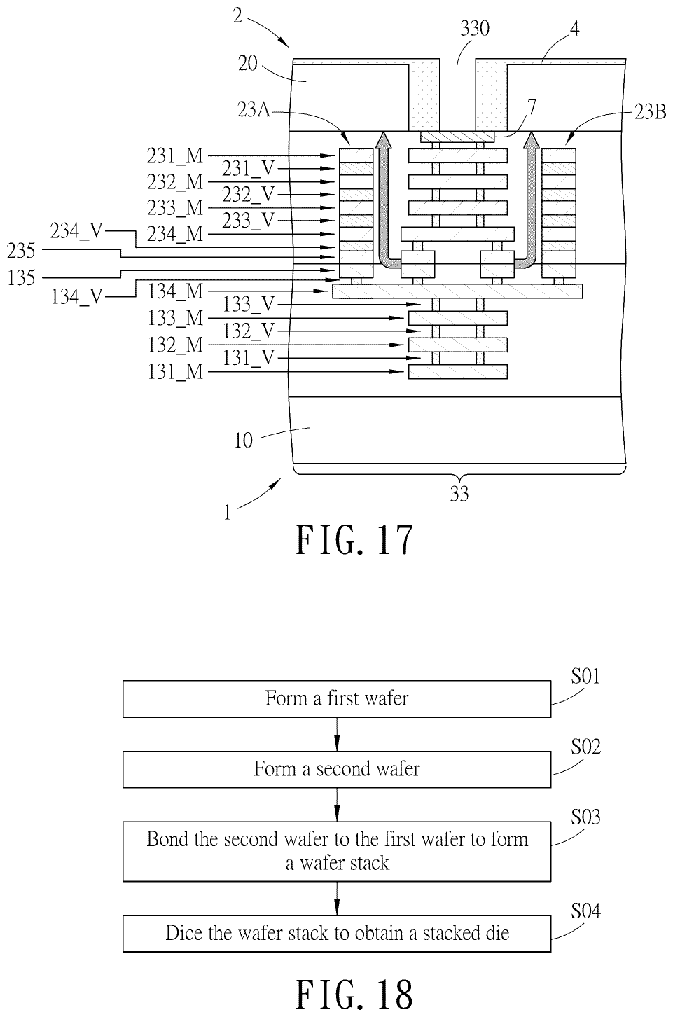

Referring to FIG. 17, a variant of the dicing region 33 is illustrated in accordance with some embodiments. This variant is similar to the variant as shown in FIG. 16, and differs in that, in this variant, the stress guiding features are formed on the second wafer. In this variant, the dicing region 33 includes a pair of stress guiding features 23A, 23B formed on the second wafer at two opposite sides of the dicing channel 330 when viewed from the top. Each of the stress guiding features 23A, 23B includes second interconnection-layer metal features disposed in the metal trench layers 231_M to 234_M and the metal via layers 231_V to 234_V, and a second RDL metal feature disposed in the redistribution layer 235 and electrically connected to the second interconnection-layer metal features of the same stress guiding feature. The second interconnection-layer metal features are connected to each other, and are vertically aligned with the second RDL metal feature of the same stress guiding feature. The first wafer includes two first RDL metal features in the redistribution layer 135, and the first RDL metal features are bonded respectively to the second RDL metal feature of the stress guiding features 23A, 23B. The combination of the stress guiding features 23A, 23B and the first RDL features can divert the stress of laser grooving or wafer sawing from horizontal propagation into vertical propagation (see the arrows in FIG. 17), thereby further reducing the probability of delamination occurring in the main circuit region 30 and/or the auxiliary circuit region 32 (see FIG. 8). In accordance with some embodiments, the variants as exemplified in FIGS. 16 and 17 can be combined together; that is, the dicing region 33 may be formed with all of the stress guiding features 13A, 13B, 23A and 23B. In accordance with some embodiments, the stress guiding feature 13A may be formed between two of the seal ring groups 12A to 12D (see FIGS. 9 to 15), and the stress guiding feature 23A may be formed between two of the seal ring groups 22A to 22D (see FIGS. 9 to 15).

Referring to FIG. 18, a method for fabricating a stacked die is illustrated in accordance with some embodiments. Further referring to FIG. 2 or 8, in step S01, the first wafer is formed to include the first main integrated circuit (see FIG. 3), the first auxiliary integrated circuit (optional, see FIG. 4) adjacent to the first main integrated circuit, at least one seal ring group (see any one of FIGS. 4 and 9 to 15) surrounding the first main integrated circuit and the first auxiliary integrated circuit, and the first part of the inspection circuit (optional, see any one of FIGS. 7, 16 and 17) adjacent to the seal ring group(s). The detailed structure of the first wafer has been described in the paragraphs, and will not be repeated herein for the sake of brevity. In step S02, the second wafer is formed to include the second main integrated circuit (see FIG. 3), the second auxiliary integrated circuit (optional, see FIG. 4) adjacent to the second main integrated circuit, at least one seal ring group (see any one of FIGS. 4 and 9 to 15) surrounding the second main integrated circuit and the second auxiliary integrated circuit, and the second part of the inspection circuit (optional, see any one of FIGS. 7, 16 and 17) adjacent to the seal ring group(s). The detailed structure of the second wafer has been described in previous paragraphs, and will not be repeated herein for the sake of brevity. In step S03, the second wafer is arranged upside down (i.e., with the front surface facing downward) and bonded to the first wafer to form the wafer stack as illustrated in FIG. 2 or 8. In step S04, the wafer stack is diced using, for example, laser grooving and/or dice sawing, according to the pattern of dicing channels (e.g., applying laser or a dicing saw in the dicing channel 330 in FIG. 7, 16 or 17) to obtain a plurality of stacked dies, at least one of which includes the first die 1 and the second die 2 that are bonded together, as illustrated hereinbefore.

In accordance with some embodiments, a semiconductor structure is provided to include a first die and a second die. The first die includes a first semiconductor substrate, a first integrated circuit disposed on the first semiconductor substrate, and a first metal seal ring structure disposed on the first semiconductor substrate and surrounding the first integrated circuit. The second die includes a second semiconductor substrate, a second integrated circuit disposed on the second semiconductor substrate, and a second metal seal ring structure disposed on the second semiconductor substrate and surrounding the second integrated circuit. The second die is disposed over the first die, the second integrated circuit is electrically connected and bonded to the first integrated circuit, and the second metal seal ring structure is bonded to the first metal seal ring structure.

In accordance with some embodiments, the first die includes a plurality of first interconnection layers stacked on the first semiconductor substrate, and a first redistribution layer (RDL) covering the first interconnection layers. The first integrated circuit has a first interconnection structure disposed in the first interconnection layers, and a first redistribution structure disposed in the first redistribution layer and electrically connected to the first interconnection structure. The first metal seal ring structure has a first seal ring group that includes a plurality of first interconnection-layer seal rings disposed in the first interconnection layers, and each of the first interconnection-layer seal rings surrounds the first interconnection structure. The first seal ring group has a first RDL seal ring disposed in the first redistribution layer, connected to one of the first interconnection-layer seal rings, and surrounding the first redistribution structure. The second die includes a plurality of second interconnection layers stacked on the second semiconductor substrate, and a second redistribution layer covering the second interconnection layers. The second integrated circuit has a second interconnection structure disposed in the second interconnection layers, and a second redistribution structure disposed in the second redistribution layer and electrically connected to the second interconnection structure. The second metal seal ring structure has a second RDL seal ring disposed in the second redistribution layer and surrounding the second redistribution structure. The second redistribution structure is bonded to the first redistribution structure, and the second RDL seal ring is bonded to the first RDL seal ring.

In accordance with some embodiments, the second metal seal ring structure has a plurality of second interconnection-layer seal rings disposed in the second interconnection layers, and each of the second interconnection-layer seal rings surrounds the second interconnection structure. The second RDL seal ring is connected to one of the second interconnection-layer seal rings.

In accordance with some embodiments, the first interconnection layers include a plurality of horizontal interconnection layers and a plurality of vertical interconnection layers, and the horizontal interconnection layers and the vertical interconnection layers are stacked alternately. The first integrated circuit includes horizontally-spreading metal patterns in the horizontal interconnection layers, and vertically-extending metal features in the vertical interconnection layers, and the vertically-extending metal features interconnect the horizontally-spreading metal patterns. The first interconnection-layer seal rings overlap each other vertically, and include a plurality of horizontal-layer seal rings and a plurality of vertical-layer seal rings, each of the horizontal-layer seal rings is disposed in one of the horizontal interconnection layers, and each of the vertical-layer seal rings is disposed in one of the vertical interconnection layers.

In accordance with some embodiments, at least one of the first interconnection-layer seal rings is electrically isolated from the first RDL seal ring.

In accordance with some embodiments, the second metal seal ring structure has a plurality of second interconnection-layer seal rings disposed in the second interconnection layers, and each of the second interconnection-layer seal rings surrounds the second interconnection structure. The second RDL seal ring is connected to one of the second interconnection-layer seal rings. The second interconnection layers include a plurality of horizontal interconnection layers and a plurality of vertical interconnection layers, and the horizontal interconnection layers and the vertical interconnection layers of the second interconnection layers are stacked alternately. The second integrated circuit includes horizontally-spreading metal patterns in the horizontal interconnection layers of the second interconnection layers, and vertically-extending metal features in the vertical interconnection layers of the second interconnection layers, and the vertically-extending metal features of the second integrated circuit interconnect the horizontally-spreading metal patterns of the second integrated circuit. The second interconnection-layer seal rings overlap each other vertically, and include a plurality of horizontal-layer seal rings and a plurality of vertical-layer seal rings, each of the horizontal-layer seal rings of the second interconnection-layer seal ring is disposed in one of the horizontal interconnection layers of the second interconnection layers, and each of the vertical-layer seal rings of the second interconnection-layer seal ring is disposed in one of the vertical interconnection layers of the second interconnection layers. At least one of the second interconnection-layer seal rings is electrically isolated from the second RDL seal ring.

In accordance with some embodiments, less than half of the first interconnection-layer seal rings are electrically isolated from the first RDL seal ring.

In accordance with some embodiments, more than half of the second interconnection-layer seal rings are electrically isolated from the second RDL seal ring.

In accordance with some embodiments, the first seal ring structure includes a second seal ring group that is horizontally adjacent to the first seal ring group. The second seal ring group includes a plurality of first interconnection-layer seal rings disposed in the first interconnection layers, and each of the first interconnection-layer seal rings in the second ring group surrounds the first interconnection structure. The second seal ring group includes a first RDL seal ring disposed in the first redistribution layer, connected to one of the first interconnection-layer seal rings in the second seal ring group, and surrounding the first redistribution structure. The first interconnection-layer seal rings in the second seal ring group overlap each other vertically, and include a plurality of horizontal-layer seal rings and a plurality of vertical-layer seal rings, each of the horizontal-layer seal rings in the second seal ring group is disposed in one of the horizontal interconnection layers, and each of the vertical-layer seal rings in the second seal ring group is disposed in one of the vertical interconnection layers. At least one of the first interconnection-layer seal rings in the second seal ring group is electrically isolated from the first RDL seal ring in the second seal ring group. One of the first interconnection layers electrically isolates said at least one of the first interconnection-layer seal rings in the first seal ring group from the first RDL seal ring in the first seal ring group, and another one of the first interconnection layers electrically isolates said at least one of the first interconnection-layer seal rings in the second seal ring group from the first RDL seal ring in the second seal ring group.

In accordance with some embodiments, the first interconnection-layer seal rings are aligned with each other vertically, and are misaligned with the second RDL seal ring vertically.

In accordance with some embodiments, the first die includes a stress guiding metal wall disposed on the first semiconductor substrate and adjacent to an edge of the first die, and extending linearly along the edge of the first die. The second die includes a metal feature aligned with and bonded to the stress guiding metal wall.

In accordance with some embodiments, a semiconductor structure is provided to include a first wafer and a second wafer. The first wafer includes a plurality of first interconnection layers stacked one on top of the other, and a first redistribution layer (RDL) disposed on the first interconnection layers. The second wafer is bonded to the first wafer, and that includes a plurality of second interconnection layers stacked one on top of the other, and a second redistribution layer disposed on the second interconnection layers. Each of the first wafer and the second wafer has a circuit region and a seal ring region, and the seal ring region surrounds the circuit region. The circuit region of the first wafer has a first redistribution structure in the first redistribution layer, the circuit region of the second wafer has a second redistribution structure in the second redistribution layer, and the second redistribution structure is bonded to the first redistribution structure. The seal ring region of the first wafer includes a first seal ring group that has a first RDL seal ring in the first redistribution layer and a plurality of first interconnection-layer seal rings in the first interconnection layers, and the first RDL seal ring is connected to one of the first interconnection-layer seal rings. The seal ring region of the second wafer has a second RDL seal ring in the second redistribution layer, and the second RLD seal ring is bonded to the first RDL seal ring. One of the first wafer and the second wafer has a pattern of dicing channels surrounding the seal ring region of said one of the first wafer and the second wafer.

In accordance with some embodiments, at least one of the first interconnection-layer seal rings of the first seal ring group is electrically isolated from the first RDL seal ring.

In accordance with some embodiments, less than half of the first interconnection-layer seal rings of the first seal ring group are electrically isolated from the first RDL seal ring.

In accordance with some embodiments, the sealing region of the second wafer has a plurality of second interconnection-layer seal rings in the second interconnection layers, and the second RDL seal ring is connected to one of the second interconnection-layer seal rings.

In accordance with some embodiments, at least one of the second interconnection-layer seal rings is electrically isolated from the second RDL seal ring, and more than half of the second interconnection-layer seal rings are electrically isolated from the second RDL seal ring.

In accordance with some embodiments, the seal ring region of the first wafer includes a second seal ring group that has a first RDL seal ring in the first redistribution layer and a plurality of first interconnection-layer seal rings in the first interconnection layers, and the first RDL seal ring in the second seal ring group is connected to one of the first interconnection-layer seal rings in the second seal ring group. At least one of the first interconnection-layer seal rings in the second ring group is electrically isolated from the first RDL seal ring in the second ring group. One of the first interconnection layers electrically isolates said at least one of the first interconnection-layer seal rings in the first seal ring group from the first RDL seal ring in the first seal ring group, and another one of the first interconnection layers electrically isolates said at least one of the first interconnection-layer seal rings in the second seal ring group from the first RDL seal ring in the second seal ring group.

In accordance with some embodiments, a method for fabricating a stacked die is provided. In one step, a first wafer is formed to include a plurality of first interconnection layers stacked one on top of the other, and a first redistribution layer (RDL) disposed on the first interconnection layers. In one step, a second wafer is formed to include a plurality of second interconnection layers stacked one on top of the other, and a second redistribution layer disposed on the second interconnection layers. In one step, the second wafer is bonded to the first wafer to form a wafer stack. In one step, the wafer stack is diced to obtain the stacked die. Each of the first wafer and the second wafer is formed to have a circuit region and a seal ring region, with the seal ring region surrounding the circuit region. The circuit region of the first wafer has a first redistribution structure in the first redistribution layer, the circuit region of the second wafer has a second redistribution structure in the second redistribution layer, and the second redistribution structure is bonded to the first redistribution structure. The seal ring region of the first wafer includes a first seal ring group that has a first RDL seal ring in the first redistribution layer and a plurality of first interconnection-layer seal rings in the first interconnection layers, and the first RDL seal ring is connected to one of the first interconnection-layer seal rings. The seal ring region of the second wafer has a second RDL seal ring in the second redistribution layer, and the second RLD seal ring is bonded to the first RDL seal ring. One of the first wafer and the second wafer has a pattern of dicing channels surrounding the seal ring region of said one of the first wafer and the second wafer. The dicing of the wafer stack is performed on the pattern of the dicing channels.

In accordance with some embodiments, at least one of the first interconnection-layer seal rings is electrically isolated from the first RDL seal ring.

In accordance with some embodiments, the seal ring region of the first wafer includes a second seal ring group that has a first RDL seal ring in the first redistribution layer and a plurality of first interconnection-layer seal rings in the first interconnection layers, and the first RDL seal ring in the second seal ring group is connected to one of the first interconnection-layer seal rings in the second seal ring group. At least one of the first interconnection-layer seal rings in the second ring group is electrically isolated from the first RDL seal ring in the second ring group. One of the first interconnection layers electrically isolates said at least one of the first interconnection-layer seal rings in the first seal ring group from the first RDL seal ring in the first seal ring group, and another one of the first interconnection layers electrically isolates said at least one of the first interconnection-layer seal rings in the second seal ring group from the first RDL seal ring in the second seal ring group.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first die that includes a first semiconductor substrate, a first integrated circuit disposed on the first semiconductor substrate, and a first metal seal ring structure disposed on the first semiconductor substrate and surrounding the first integrated circuit; and
a second die that includes a second semiconductor substrate, a second integrated circuit disposed on the second semiconductor substrate, and a second metal seal ring structure disposed on the second semiconductor substrate and surrounding the second integrated circuit;
wherein the second die is disposed over the first die, the second integrated circuit is electrically connected and bonded to the first integrated circuit, and the second metal seal ring structure is bonded to the first metal seal ring structure.

2. The semiconductor structure according to claim 1, wherein the first die includes a plurality of first interconnection layers stacked on the first semiconductor substrate, and a first redistribution layer (RDL) covering the first interconnection layers;
wherein the first integrated circuit has a first interconnection structure disposed in the first interconnection layers, and a first redistribution structure disposed in the first redistribution layer and electrically connected to the first interconnection structure;
wherein the first metal seal ring structure has a first seal ring group that includes a plurality of first interconnection-layer seal rings disposed in the first interconnection layers, and each of the first interconnection-layer seal rings surrounds the first interconnection structure;
wherein the first seal ring group has a first RDL seal ring disposed in the first redistribution layer, connected to one of the first interconnection-layer seal rings, and surrounding the first redistribution structure;
wherein the second die includes a plurality of second interconnection layers stacked on the second semiconductor substrate, and a second redistribution layer covering the second interconnection layers;
wherein the second integrated circuit has a second interconnection structure disposed in the second interconnection layers, and a second redistribution structure disposed in the second redistribution layer and electrically connected to the second interconnection structure;
wherein the second metal seal ring structure has a second RDL seal ring disposed in the second redistribution layer and surrounding the second redistribution structure; and
wherein the second redistribution structure is bonded to the first redistribution structure, and the second RDL seal ring is bonded to the first RDL seal ring.

3. The semiconductor structure according to claim 2, wherein the second metal seal ring structure has a plurality of second interconnection-layer seal rings disposed in the second interconnection layers, and each of the second interconnection-layer seal rings surrounds the second interconnection structure; and
wherein the second RDL seal ring is connected to one of the second interconnection-layer seal rings.

4. The semiconductor structure according to claim 2, wherein the first interconnection layers include a plurality of horizontal interconnection layers and a plurality of vertical interconnection layers, and the horizontal interconnection layers and the vertical interconnection layers are stacked alternately;
wherein the first integrated circuit includes horizontally-spreading metal patterns in the horizontal interconnection layers, and vertically-extending metal features in the vertical interconnection layers, and the vertically-extending metal features interconnect the horizontally-spreading metal patterns; and
wherein the first interconnection-layer seal rings overlap each other vertically, and include a plurality of horizontal-layer seal rings and a plurality of vertical-layer seal rings, each of the horizontal-layer seal rings is disposed in one of the horizontal interconnection layers, and each of the vertical-layer seal rings is disposed in one of the vertical interconnection layers.

5. The semiconductor structure according to claim 4, wherein at least one of the first interconnection-layer seal rings is electrically isolated from the first RDL seal ring.

6. The semiconductor structure according to claim 5, wherein the second metal seal ring structure has a plurality of second interconnection-layer seal rings disposed in the second interconnection layers, and each of the second interconnection-layer seal rings surrounds the second interconnection structure;
wherein the second RDL seal ring is connected to one of the second interconnection-layer seal rings;
wherein the second interconnection layers include a plurality of horizontal interconnection layers and a plurality of vertical interconnection layers, and the horizontal interconnection layers and the vertical interconnection layers of the second interconnection layers are stacked alternately;
wherein the second integrated circuit includes horizontally-spreading metal patterns in the horizontal interconnection layers of the second interconnection layers, and vertically-extending metal features in the vertical interconnection layers of the second interconnection layers, and the vertically-extending metal features of the second integrated circuit interconnect the horizontally-spreading metal patterns of the second integrated circuit;
wherein the second interconnection-layer seal rings overlap each other vertically, and include a plurality of horizontal-layer seal rings and a plurality of vertical-layer seal rings, each of the horizontal-layer seal rings of the second interconnection-layer seal ring is disposed in one of the horizontal interconnection layers of the second interconnection layers, and each of the vertical-layer seal rings of the second interconnection-layer seal ring is disposed in one of the vertical interconnection layers of the second interconnection layers; and
wherein at least one of the second interconnection-layer seal rings is electrically isolated from the second RDL seal ring.

7. The semiconductor structure according to claim 6, wherein less than half of the first interconnection-layer seal rings are electrically isolated from the first RDL seal ring.

8. The semiconductor structure according to claim 7, wherein more than half of the second interconnection-layer seal rings are electrically isolated from the second RDL seal ring.

9. The semiconductor structure according to claim 5, wherein the first seal ring structure includes a second seal ring group that is horizontally adjacent to the first seal ring group;
wherein the second seal ring group includes a plurality of first interconnection-layer seal rings disposed in the first interconnection layers, and each of the first interconnection-layer seal rings in the second ring group surrounds the first interconnection structure;
wherein the second seal ring group includes a first RDL seal ring disposed in the first redistribution layer, connected to one of the first interconnection-layer seal rings in the second seal ring group, and surrounding the first redistribution structure;
wherein the first interconnection-layer seal rings in the second seal ring group overlap each other vertically, and include a plurality of horizontal-layer seal rings and a plurality of vertical-layer seal rings, each of the horizontal-layer seal rings in the second seal ring group is disposed in one of the horizontal interconnection layers, and each of the vertical-layer seal rings in the second seal ring group is disposed in one of the vertical interconnection layers;
wherein at least one of the first interconnection-layer seal rings in the second seal ring group is electrically isolated from the first RDL seal ring in the second seal ring group; and
wherein one of the first interconnection layers electrically isolates said at least one of the first interconnection-layer seal rings in the first seal ring group from the first RDL seal ring in the first seal ring group, and another one of the first interconnection layers electrically isolates said at least one of the first interconnection-layer seal rings in the second seal ring group from the first RDL seal ring in the second seal ring group.

10. The semiconductor structure according to claim 2, wherein the first interconnection-layer seal rings are aligned with each other vertically, and are misaligned with the second RDL seal ring vertically.

11. The semiconductor structure according to claim 1, wherein the first die includes a stress guiding metal wall disposed on the first semiconductor substrate and adjacent to an edge of the first die, and extending linearly along the edge of the first die; and
wherein the second die includes a metal feature aligned with and bonded to the stress guiding metal wall.

12. A semiconductor structure, comprising:
a first wafer that includes a plurality of first interconnection layers stacked one on top of the other, and a first redistribution layer (RDL) disposed on the first interconnection layers; and
a second wafer that is bonded to the first wafer, and that includes a plurality of second interconnection layers stacked one on top of the other, and a second redistribution layer disposed on the second interconnection layers,
wherein each of the first wafer and the second wafer has a circuit region and a seal ring region, and the seal ring region surrounds the circuit region;
wherein the circuit region of the first wafer has a first redistribution structure in the first redistribution layer, the circuit region of the second wafer has a second redistribution structure in the second redistribution layer, and the second redistribution structure is bonded to the first redistribution structure;
wherein the seal ring region of the first wafer includes a first seal ring group that has a first RDL seal ring in the first redistribution layer and a plurality of first interconnection-layer seal rings in the first interconnection layers, and the first RDL seal ring is connected to one of the first interconnection-layer seal rings;
wherein the seal ring region of the second wafer has a second RDL seal ring in the second redistribution layer, and the second RLD seal ring is bonded to the first RDL seal ring; and
wherein one of the first wafer and the second wafer has a pattern of dicing channels surrounding the seal ring region of said one of the first wafer and the second wafer.

13. The semiconductor structure according to claim 12, wherein at least one of the first interconnection-layer seal rings of the first seal ring group is electrically isolated from the first RDL seal ring.

14. The semiconductor structure according to claim 13, wherein less than half of the first interconnection-layer seal rings of the first seal ring group are electrically isolated from the first RDL seal ring.

15. The semiconductor structure according to claim 14, wherein the sealing region of the second wafer has a plurality of second interconnection-layer seal rings in the second interconnection layers, and the second RDL seal ring is connected to one of the second interconnection-layer seal rings.

16. The semiconductor structure according to claim 15, wherein at least one of the second interconnection-layer seal rings is electrically isolated from the second RDL seal ring, and more than half of the second interconnection-layer seal rings are electrically isolated from the second RDL seal ring.

17. The semiconductor structure according to claim 13, wherein the seal ring region of the first wafer includes a second seal ring group that has a first RDL seal ring in the first redistribution layer and a plurality of first interconnection-layer seal rings in the first interconnection layers, and the first RDL seal ring in the second seal ring group is connected to one of the first interconnection-layer seal rings in the second seal ring group;
wherein at least one of the first interconnection-layer seal rings in the second ring group is electrically isolated from the first RDL seal ring in the second ring group; and
wherein one of the first interconnection layers electrically isolates said at least one of the first interconnection-layer seal rings in the first seal ring group from the first RDL seal ring in the first seal ring group, and another one of the first interconnection layers electrically isolates said at least one of the first interconnection-layer seal rings in the second seal ring group from the first RDL seal ring in the second seal ring group.

18. A method for fabricating a stacked die, comprising:
forming a first wafer that includes a plurality of first interconnection layers stacked one on top of the other, and a first redistribution layer (RDL) disposed on the first interconnection layers;
forming a second wafer that includes a plurality of second interconnection layers stacked one on top of the other, and a second redistribution layer disposed on the second interconnection layers;
bonding the second wafer to the first wafer to form a wafer stack; and
dicing the wafer stack to obtain the stacked die;
wherein each of the first wafer and the second wafer is formed to have a circuit region and a seal ring region, with the seal ring region surrounding the circuit region;
wherein the circuit region of the first wafer has a first redistribution structure in the first redistribution layer, the circuit region of the second wafer has a second redistribution structure in the second redistribution layer, and the second redistribution structure is bonded to the first redistribution structure;
wherein the seal ring region of the first wafer includes a first seal ring group that has a first RDL seal ring in the first redistribution layer and a plurality of first interconnection-layer seal rings in the first interconnection layers, and the first RDL seal ring is connected to one of the first interconnection-layer seal rings;
wherein the seal ring region of the second wafer has a second RDL seal ring in the second redistribution layer, and the second RLD seal ring is bonded to the first RDL seal ring;
wherein one of the first wafer and the second wafer has a pattern of dicing channels surrounding the seal ring region of said one of the first wafer and the second wafer; and
wherein the dicing of the wafer stack is performed on the pattern of the dicing channels.

19. The method according to claim 18, wherein at least one of the first interconnection-layer seal rings is electrically isolated from the first RDL seal ring.

20. The method according to claim 19, wherein the seal ring region of the first wafer includes a second seal ring group that has a first RDL seal ring in the first redistribution layer and a plurality of first interconnection-layer seal rings in the first interconnection layers, and the first RDL seal ring in the second seal ring group is connected to one of the first interconnection-layer seal rings in the second seal ring group;
wherein at least one of the first interconnection-layer seal rings in the second ring group is electrically isolated from the first RDL seal ring in the second ring group; and
wherein one of the first interconnection layers electrically isolates said at least one of the first interconnection-layer seal rings in the first seal ring group from the first RDL seal ring in the first seal ring group, and another one of the first interconnection layers electrically isolates said at least one of the first interconnection-layer seal rings in the second seal ring group from the first RDL seal ring in the second seal ring group.
